(19) United States
(12) Patent Application Publication
(10) Pub. No.: US 2004/0266191 A1
(43) Pub. Date: Dec. 30, 2004

(54) Process for the wet-chemical surface treatment of a semiconductor wafer

(76) Inventors: Gunter Schwab, Neuotting (DE); Helmut Franke, Burghausen (DE); Helmut Paltzer, Kastl (DE); Manfred Schofberger, Reut (DE); Maximilian Stadler, Haiming (DE)

Correspondence Address: WILLIAM COLLARD, COLLARD & ROE, P.C., 1077 NORTHERN BOULEVARD, ROSLYN, NY, 11576, US

(21) Appl. No.: 10/877,682

(22) Filed: Jun. 25, 2004

(30) Foreign Application Priority Data
Jun. 26, 2003 (DE) 103 28 845.7

(51) Int. Cl. H01L 21/44; H01L 21/302; H01L 21/461

(52) U.S. Cl. 438/690

(57) ABSTRACT

A process for the wet-chemical surface treatment of a semiconductor wafer has the semiconductor wafer being treated with an acidic liquid, with at most 10 μm of material being removed from each surface of the semiconductor wafer, and then this wafer is treated with an alkaline liquid, with at least sufficient material being removed for the crystal regions which have been damaged by a previous mechanical treatment to be completely removed.

### CROSS REFERENCE TO RELATED APPLICATIONS

Applicants claim priority under 35 U.S.C. §119 of German Application No. 103 28 845.7 filed Jun. 26, 2003.

### BACKGROUND OF THE INVENTION

1. Field of the Invention

The present invention relates to a process for the wet-chemical surface treatment of a semiconductor wafer by means of a sequence of treatment steps in which various liquids act on the surface of the semiconductor wafer.

2. The Prior Art

The ever increasing miniaturization involved in the fabrication of electronic components is imposing ever higher demands on the surface quality of the semiconductor materials, such as in particular silicon, which are generally used in wafer form. This applies not only to the geometric quality of the surfaces, but also to their purity, chemical condition and freedom from particles and spots.

To allow these parameters to be influenced and controlled in a reproducible way, in particular wet-chemical surface treatment processes have been developed. These processes are employed in particular after mechanical surface treatments, such as grinding, lapping or polishing. According to the prior art, these processes are characterized by a sequence of treatment steps in which various aqueous, acidic or alkaline liquids and/or liquids in conjunction with gases, act on the surfaces. Wet-chemical surface treatment processes which are associated with the removal of material from the surface are also known as etching processes.

There are two etching processes used in practice for the etching of semiconductor wafers, involving the use of alkaline or acidic liquids:

The alkaline etch can be described (on the basis of the example of silicon) by the following reaction equation:

Si+2 OH⁻+H₂O→SiO₃²⁻+2 H₂

To obtain wafers without any spots and to achieve sufficiently high material-removal rates, the process has to take place at high temperatures. The temperatures are to be set to at least 100° C., since lower temperatures lead to the formation of spots which can only be removed again by an additional polishing step, which increases the production costs of the semiconductor wafer. The alkaline etch generally takes place directly after a mechanical material-removal step, for example a lapping or grinding step. It can be used both to clean and purify the wafer surface and to remove the crystal regions which were damaged during the mechanical material-removal step.

However, a semiconductor wafer which is substantially free of metal contamination cannot be produced using alkaline liquids, even with ultrapure chemicals. In the case of mechanically treated wafers, elements which diffuse readily, such as copper or nickel, are to be found both at the surface and in the damage region. Also at elevated temperatures these elements diffuse into the lower layers of the semiconductor wafer and consequently are no longer accessible to surface cleaning methods. On the other hand, one advantage is that the alkaline etch can be made relatively simple in terms of process engineering, since the hydrogen which is formed ensures the required mass transfer. Therefore, homogeneous removal of material over the entire surface of the wafer is possible without major outlay. This means that the wafer shape (geometry) which has been set by the mechanical material-removal step is retained as far as possible.

In the case of the acidic etch, silicon is generally oxidized using nitric acid (HNO₃), and the silicon dioxide (SiO₂) formed is dissolved using hydrofluoric acid (HF):

Si+HNO₃→SiO₂+2 HNO₂ HNO₂→NO+NO₂+H₂O SiO₂+6 HF→H₂SiF₆+2 H₂O

Since this process can take place at low temperatures and, moreover, has metal-dissolving properties, it can be used to produce semiconductor wafers which are substantially free of metal impurities.

However, the acidic etch has the drawback that homogeneous removal of material can only be realized to a limited extent and at considerable cost. Consequently the wafer geometry which was set by the mechanical material-removal step deteriorates again during the acidic etch. Particularly in the region close to the edge, it is not possible to maintain the wafer geometry if more than 10 μm of material is being removed from each surface of the wafer.

Therefore, attempts have been made to combine the alkaline etch and the acidic etch with one another in an advantageous way. For example, the alkaline etch is generally employed in the form of a brief cleaning etch, in which the particles adhering to the wafer surface are removed. This does not involve complete removal of the crystal regions which have been damaged by the prior mechanical treatment. This only occurs during a subsequent acidic etch, in which the metals which have diffused in are also removed. Wet-chemical surface treatment processes of this type in which, if appropriate in combination with further wet-chemical steps, first of all an alkaline etch and then an acidic etch are used, are described in DE19953152C1, U.S. Pat. No. 6,239,039B1 and WO02/01616A1.

However, even these combined processes do not completely satisfy the increasing demands imposed on the geometry of the semiconductor wafers and the absence of metals therein. In particular, although an increase in the amount of material removed in the alkaline etch at the expense of the acidic etch leads to an improvement in the wafer geometry, it also has an adverse effect on the removal of the metal impurities, and vice versa. Moreover, an increase in the amount of material removed by alkaline etching leads to a more pronounced alkaline etching structure, which generally leads to an increase in the roughness values. Locations with increased damage are etched disproportionately and therefore leave behind depressions in the surface.

### SUMMARY OF THE INVENTION

Therefore, it is an object of the present invention to provide a process for the wet-chemical surface treatment of a semiconductor wafer which is able to satisfy the demands imposed with regard to the absence of metals and the geometry of the semiconductor wafer equally well.

The above object is achieved according to the invention by providing a process for the wet-chemical surface treatment of a semiconductor wafer, in which the semiconductor wafer—is treated with an acidic liquid, with at most 10 μm of material being removed from each surface of the semiconductor wafer, and then is treated with an alkaline liquid, with at least sufficient material being removed for the crystal regions which have been damaged by a previous mechanical treatment to be completely removed.

The process according to the invention is distinguished, compared to the prior art, by the fact that the semiconductor wafer is treated firstly with an acidic liquid and then with an alkaline liquid, with chemical removal of material taking place in each instance. During the acidic etch, at most 10 μm of material is removed from each surface of the wafer. This is sufficient to remove the metal impurities, for example copper or nickel, which are present at the wafer surface and in the regions close to the surface. At the same time, the amount of material removed is so small that the geometry of the semiconductor wafer which has been determined by the prior mechanical treatment is only slightly detrimentally affected. During the subsequent alkaline etch, sufficient material is removed from the semiconductor wafer, which is already substantially metal-free following the acidic etch, for the crystal regions which have been damaged during the mechanical treatment to be completely removed.

The process sequence according to the invention allows the advantages of the two etching technologies to be optimally combined. It ensures that the wafer geometry which has been established by the mechanical treatment (e.g. lapping or grinding) is retained and therefore offers optimum preconditions for subsequent polishing of at least the front surface of the semiconductor wafer.

### DETAILED DESCRIPTION OF PREFERRED EMBODIMENTS

The following text describes preferred embodiments of the invention, giving the process parameters which are optimum for silicon. However, the process is not restricted to silicon. To this end, the process according to the invention is broken down into steps a) to e), with the surface of the semiconductor wafer being treated with the following liquids, in the order indicated:

a) with a first cleaning liquid, which is suitable for removing particles adhering to the surface of the semiconductor wafer,

b) with an acidic liquid, with at most 10 μm of material being removed from each surface of the semiconductor wafer,

c) with the first cleaning liquid,

d) with a second cleaning liquid, which is suitable for removing metal impurities from the surface of the semiconductor wafer, and

e) with an alkaline liquid, with at least sufficient material being removed for the crystal regions which have been damaged by a prior mechanical treatment to be completely removed.

Steps b) and e) are absolutely imperative, while steps a), c) and d) are advantageous but may also be omitted.

Preferably, first of all, in step a) the particles adhering to the surface of the semiconductor wafer (e.g. lapping abrasive residues) are removed by means of a particle cleaning. To do this, it is preferable to use a cleaning liquid which contains water and a surfactant. The surfactant in the aqueous cleaning liquid rearranges the particles which are to be cleaned off and thereby assists with removal of the particles. It is preferable for the pH of the cleaning liquid to be in the range from 10 to 12. The temperatures used for this cleaning are preferably at most 90° C., particularly preferably at most 60° C. This ensures that the metals which are present at the surface of the semiconductor wafer or in regions close to the surface do not diffuse into deeper layers of the semiconductor wafer. To assist the cleaning action, it is preferable to simultaneously employ ultrasound. Without the action of ultrasound, the cleaning action is reduced, which means that longer treatment times and/or more treatment baths are required to clean the wafers.

In step b), at most 10 μm of material is removed from each surface of the semiconductor wafer. To achieve the minimum possible change in the wafer geometry, it is preferable for at most 5 μm of material to be removed from each surface of the wafer. The acidic etch removes not only the metals which are present at the surface of the semiconductor wafer but also metals which are bound in the crystal regions which have been damaged by the prior mechanical treatment, without the wafer geometry being significantly altered. The acidic liquid preferably contains water, hydrofluoric acid and nitric acid, with the concentration of the nitric acid preferably being in the range from 60% to 80%, and the concentration of the hydrofluoric acid preferably being in the range from 0.5% to 5%. (All the percentages indicated relate to the percentage by weight of the compound in question based on the total weight of the solution.) The temperature of the liquid is preferably in the range from 10° C. to 30° C., particularly preferably in the range from 15° C. to 25° C. The acidic etch in step b) is preferably carried out as described in EP625795A1, in order for material to be removed as homogeneously as possible.

In a subsequent step c), particles which may still be present on the surface of the semiconductor wafer after the acidic etch can be removed by means of a further particle cleaning similar to step a). It is preferable to carry out at least one of the steps a) and c), and it is particularly preferable to carry out both of these steps.

Immediately before the alkaline etch e) it is preferable to carry out a further cleaning step d) using a second cleaning liquid which is suitable for removing metal impurities from the surface of the semiconductor wafer. This second cleaning liquid preferably contains water, hydrofluoric acid (HF) and ozone (O₃). It is preferable for the atmosphere above the cleaning liquid also to contain ozone. It is preferable for the concentration of the hydrofluoric acid to be in the range from 0.01% to 2%. It is also preferable for the liquid to be saturated with ozone. Cleaning away metals at this point in the process is expedient in order to prevent metal impurities which have remained following the preceding steps or have been newly added from being able to diffuse into the semiconductor wafer at the high temperatures of the alkaline etch.

Then, in step e), the semiconductor wafer is treated with an alkaline liquid. The alkaline liquid preferably contains water and an alkali metal hydroxide, with sodium hydroxide (NaOH) or potassium hydroxide (KOH) being particularly preferred. It is preferable for the concentration of the alkali metal hydroxide to be in the range from 25% to 60%. The use of high-purity chemicals is also particularly preferred, in order to avoid further contamination with metals, in which case the concentration of iron, copper, nickel and chromium should preferably in each case be less than 5 ppt. The temperature during the treatment is preferably in the range from 70° C. to 125° C. It is advantageous for the semiconductor wafer to be moved, for example rotated, during the treatment. The alkali etch removes at least sufficient material for the crystal regions which have been damaged by a prior mechanical treatment to be completely removed.

After the wet-chemical treatment according to the invention, the semiconductor wafer is preferably dried in accordance with the prior art, in which case, by way of example, isopropanol dryers (in particular Marangoni dryers), hot water dryers or rinser dryers are used. The drying is preferably selected to be such that it has no adverse effect on the surface quality, in particular with regard to metal and particle contamination. It is particularly preferred to use an HF/ozone drier.

The process according to the invention can be applied to semiconductor wafers which have previously been mechanically treated. It is preferably applied to silicon wafers and in particular to single-crystal silicon wafers of any desired diameter.

Accordingly, while a few embodiments of the present invention have been shown and described, it is to be understood that many changes and modifications may be made thereunto without departing from the spirit and scope of the invention as defined in the appended claims.

What is claimed is:

1. A process for the wet-chemical surface treatment of a semiconductor wafer, comprises the steps of
treating the semiconductor wafer with an acidic liquid, with at most 10 μm of material being removed from each surface of the semiconductor wafer, and then
treating the semiconductor wafer with an alkaline liquid, with at least sufficient material being removed for the crystal regions which have been damaged by a previous mechanical treatment to be completely removed.

2. The process as claimed in claim 1,
wherein the semiconductor wafer, before being treated with the alkaline liquid, is treated at least once with a first cleaning liquid which is suitable for removing particles adhering to the surface of the semiconductor wafer.

3. The process as claimed in claim 1,
wherein the semiconductor wafer, immediately before being treated with the alkaline liquid, is treated with a second cleaning liquid which is suitable for removing metal impurities from the surface of the semiconductor wafer.

4. The process as claimed in claim 3,
wherein the surface of the semiconductor wafer is treated, in steps a) to e) in the order given, with the following liquids:
a) with a first cleaning liquid, which is suitable for removing particles adhering to the surface of the semiconductor wafer,
b) with an acidic liquid, with at most 10 μm of material being removed from each surface of the semiconductor wafer,
c) with the first cleaning liquid,
d) with a second cleaning liquid, which is suitable for removing metal impurities from the surface of the semiconductor wafer, and
e) with an alkaline liquid, with at least sufficient material being removed for the crystal regions which have been damaged by a prior mechanical treatment to be completely removed.

5. The process as claimed in claim 1,
wherein the acidic liquid contains water, hydrofluoric acid and nitric acid.

6. The process as claimed in claim 1,
wherein at most 5 μm of material is removed from each surface of the semiconductor wafer during the treatment with the acidic liquid.

7. The process as claimed in claims 1,
wherein the alkaline liquid contains water and an alkali metal hydroxide.

8. The process as claimed in claim 7,
wherein the alkali metal hydroxide is selected from the group consisting of sodium hydroxide and potassium hydroxide.

9. The process as claimed in claim 2,
wherein the first cleaning liquid contains water and a surfactant.

10. The process as claimed in claim 2,
wherein the treatment with the first cleaning liquid takes place at a temperature of at most 90° C.

11. The process as claimed in claim 2,
wherein the treatment with the first cleaning liquid is carried out simultaneously with ultrasound.

12. The process as claimed in claim 3,
wherein the second cleaning liquid contains water, hydrofluoric acid and ozone.

13. The process as claimed in claim 1,
wherein the semiconductor wafer is a silicon wafer.
